(19) United States
(12) Patent Application Publication
(10) Pub. No.: US 2020/0098725 A1
(43) Pub. Date: Mar. 26, 2020

(54) SEMICONDUCTOR PACKAGE OR SEMICONDUCTOR PACKAGE STRUCTURE WITH DUAL-SIDED INTERPOSER AND MEMORY

(71) Applicant: Intel Corporation, Santa Clara, CA (US)

(72) Inventors: Shawna M. Liff, Scottsdale, AZ (US); Adel A. Elsherbini, Chandler, AZ (US); Johanna M. Swan, Scottsdale, AZ (US); Gerald S. Pasdast, San Jose, CA (US); Babak Sabi, Portland, OR (US)

(73) Assignee: Intel Corporation, Santa Clara, CA (US)

(21) Appl. No.: 16/143,339

(22) Filed: Sep. 26, 2018

(51) Int. Cl. H01L 25/065; H01L 25/00; H01L 23/00

(52) U.S. Cl. CPC H01L 25/0652; H01L 25/50; H01L 24/17; H01L 2224/16225; H01L 2225/06517; H01L 2224/17177; H01L 2224/17181; H01L 24/16

(57) ABSTRACT

Embodiments herein relate to a semiconductor package or a semiconductor package structure that includes an interposer with opposing first and second sides. A memory and a processing unit may be coupled with the second side of the interposer, and the first side of the interposer may be to couple with the substrate. The processing unit and memory may be communicatively coupled with one another and the substrate by the interposer. Other embodiments may be described or claimed.

### BACKGROUND

Compute intensive applications such as machine learning, computer vision, or deep learning may drive a need for more compute power or acceleration of computation power. This need may result in leveraging of processor cores, additional executable units (EUs) via general processing units (GPUs), additional field programmable gate arrays (FPGAs), etc. Consequently, manufacturers may pair more GPUs or FPGAs on a single semiconductor package, and pair the GPUs/FPGAs with local memory to enable low-latency/high-speed access to the memory. Often, the size and performance of these systems may be limited by the maximum thermal dissipative power of the system, and the cost-affordable breaking point of packaging yield.

### BRIEF DESCRIPTION OF THE DRAWINGS

FIG. 1 depicts an example system that includes a semiconductor package with a dual-sided interposer, in accordance with various embodiments.

FIG. 2 depicts an alternative example system that includes a semiconductor package with a dual-sided interposer, in accordance with various embodiments.

FIG. 3 depicts an example semiconductor package that may use one or more of the semiconductor package structures described herein, in accordance with various embodiments.

FIG. 4 depicts an example semiconductor package structure with a dual-sided interposer, in accordance with various embodiments.

FIG. 5 depicts an alternative example semiconductor package structure with a dual-sided interposer, in accordance with various embodiments.

FIG. 6 depicts an example semiconductor package structure with a dual-sided interposer, in accordance with various embodiments.

FIG. 7 depicts an alternative example semiconductor package structure with a dual-sided interposer, in accordance with various embodiments.

FIG. 8 depicts an alternative example semiconductor package structure with a dual-sided interposer, in accordance with various embodiments.

FIG. 9 depicts an alternative example semiconductor package structure with a dual-sided interposer, in accordance with various embodiments.

FIG. 10 depicts an alternative example semiconductor package structure with a dual-sided interposer, in accordance with various embodiments.

FIG. 11 depicts an example technique that may be used to manufacture one or more of the semiconductor packages or semiconductor package structures depicted herein, in accordance with various embodiments.

FIG. 12 illustrates an example device, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature formed, deposited, or otherwise disposed on a second feature,” may mean that the first feature is formed, deposited, or disposed over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise.

Additionally, descriptions of Figures herein may be made with reference to specific elements illustrated and enumerated in the Figures. However, it will be understood that each and every element may not be enumerated for the sake of clarity, conciseness, and lack of redundancy. Rather, only one of some repeated elements may be enumerated and discussed, and other similarly situated elements may include aspects of the discussed elements.

Generally, as used herein, “die” is used as a generic term unless otherwise stated. “Die” may refer to a monolithic silicon or other semiconductor die, a fan-out or fan-in die package, a die stack, etc. The die stack may be, for example, a wafer stack, a die stack, or some other stack.

As noted previously, in many cases memory is being used on a semiconductor package with a processing unit such as a central processing unit (CPU), a FPGA, or a GPU to increase the speed and efficiency of the semiconductor package. In some embodiments, the memory may be a high bandwidth memory (HBM), which may for example be a memory that is in accordance with the joint electron device engineering council (JEDEC) “HIGH BANDWIDTH MEMORY (HBM) DRAM” document JESD235A, published November, 2015. Generally, the HBM may be referred to as a “memory stack” and may include a number of memory slices, that may be coupled with a base die that serves as a memory controller. The memory stack may include, for example, two, four, or eight slices, each of which may be approximately one gigabyte (GB) of memory. In embodiments, each stack may send or receive data on a bus that may have a bandwidth of, for example, 256 bits per memory slice.

However, in some cases the stacks may be relatively expensive and there may be a negative impact by compounding multiple die attaches on a single semiconductor package. As a result, manufacturers may optimize the number of stacks, and the capacity of the stack, for a specific product function or workload. Furthermore, thermal constraints related to the stacks may be important. Specifically, for maximum performance the junction temperature of the stack's memory controller may need to be less than or equal to approximately 95 degrees Celsius. Sometimes, cooling of the memory controller may become challenging as the thickness of the memory stack increases.

Embodiments herein may relate to use of an integrated circuit (IC) that includes interconnects on both the top and the bottom of the IC. The interconnects may be based on a traditional through silicon via (TSV) process, or a device stacking approach with interconnects on both sides. The IC that includes interconnects on both the top and the bottom may be referred to as a dual-sided interposer. In embodiments, the dual-sided interposer may be used to stitch two or more one-sided ICs, or two or more composite stacks (e.g., an HBM stack) together. In embodiments, one or more memory die may also be coupled with the dual-sided interposer. The resulting semiconductor packages or semiconductor package structures may be able to satisfy future deep learning, machine learning, artificial intelligence, virtual reality, or cloud workloads, or some other type of resource intensive computer application.

By enabling this active stitching, it may be possible to increase the data rate between a processing unit and the memory, or reduce the power at the interface between the processing unit and the memory. Additionally, embodiments herein may lower cost by embedding a logic IC on the stitching bridge or the dual-sided interposer, thereby enabling an end user to purchase only the memory without the logic circuit. Additionally, the inclusion of an additional active or passive interposer below a memory stack that includes its own control logic may improve thermal dissipation, increase yield, decrease power, or increase bandwidth a multi-die stitch systems.

More generally, to reduce the data rate between a processing unit and memory, or to reduce the power at the processing unit/memory interface, embodiments herein may relate to use of an active bridge or a dual-sided interposer that connects two or more elements of a computing system. As used herein, an “active” element may refer to an element such as a dual-sided bridge, an interposer, or some other element that includes logic. The logic may be in the form of, for example, transistors, circuits, or some other type of logic. The logic may be configured to alter one or more signals propagating through the element in some manner. By contrast, a “passive” element may refer to an element that does not have such logic enabled by the inclusion of transistors. Rather, the element may be configured to allow the signals to propagate through the element without logically changing the signals. The stitching bridge itself may be a dual-sided interposer as described above, wherein the bridge may have interconnects at two opposing sides of the bridge.

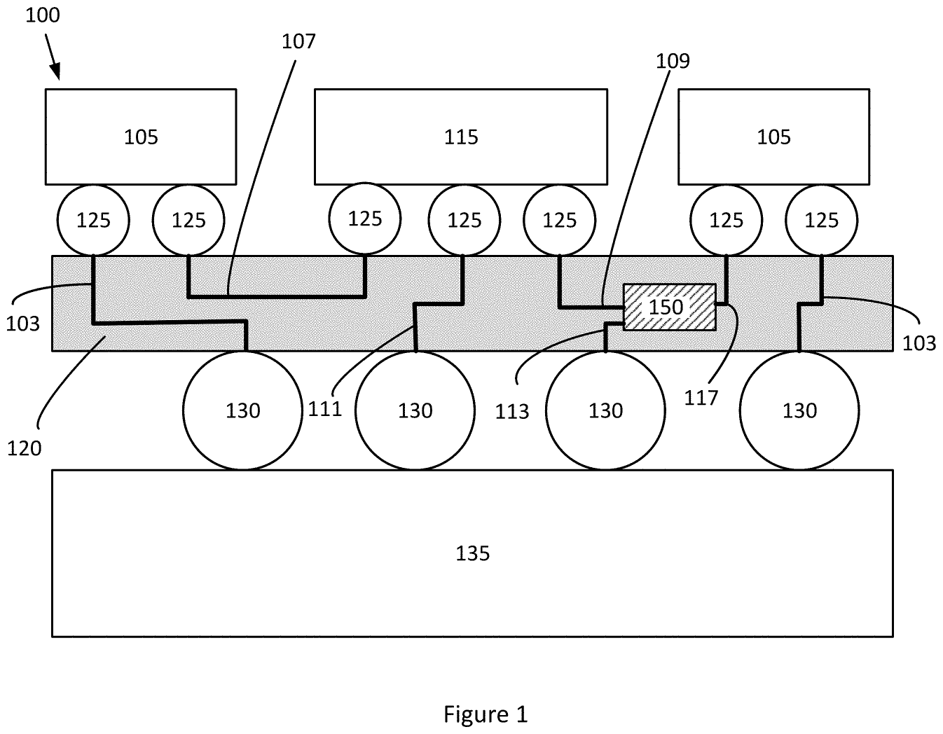

FIG. 1 depicts an example system that includes a semiconductor package with a dual-sided interposer, in accordance with various embodiments. Specifically, FIG. 1 depicts a semiconductor package 100 that may include one or more processing units 105. The processing unit 105 may be, for example, a GPU, an FPGA, a CPU, a multi-core CPU, or disaggregated CPU, GPU or FPGA sub-units, or some other type of processing unit. In some embodiments, the semiconductor package 100 may include a plurality of processing units such as processing units 105, which may be a small array of core or GPU or FPGA elements which when in aggregate have the function of a larger monolithic processing unit.

Semiconductor package 100 may further include a memory 115. The memory 115 may be, for example, a dynamic random-access memory (DRAM), an HBM memory, a non-volatile memory (NVM), an embedded DRAM (eDRAM), a static random-access memory (SRAM), a memory stack that includes a plurality of memory slices as described above, or some other type of memory. In embodiments where the memory is a memory stack that includes a plurality of slices, each of the memory slices may be a 1 GB DRAM chip, or some other type of memory. In some embodiments, the memory 115 may include a memory controller as part of the memory stack.

The processing unit(s) 105 and memory 115 may be coupled with an interposer 120 by solder bumps 125. In embodiments, the solder bumps 125 may include tin, silver, nickel, copper, lead, bismuth, combinations thereof, or some other solder or metal interconnect material.

Similarly, the interposer 120 may be coupled with a substrate 135 by electrical interconnects such as redistribution layer of copper interconnects or in combination with solder bumps shown in 130. Similarly to solder bumps 125, solder bumps 130 may be formed of a solder material such as tin, silver, copper, nickel lead, bismuth, combinations thereof, or some other solder material. The substrate 135 may be a cored or coreless substrate. It may be, for example, a printed circuit board (PCB), a ceramic or glass or silicon interposer, or some other type of substrate. Furthermore, in embodiments the interposer 120 may be embedded within redistribution layers on both the top, sides and bottoms or some combination thereof, or directly embedded within the substrate 135.

As can be seen in FIG. 1, solder bumps 130 may be larger than solder bumps 125. Similarly, solder bumps 130 may have a larger pitch than solder bumps 125. As used herein, “pitch” may refer to a distance from the center of one solder bump to a neighboring solder bump. However, in other embodiments solder bumps 125 may have a similar diameter to that of solder bumps 130, or may even be larger than solder bumps 130. Similarly, in other embodiments solder bumps 125 may have a pitch similar to that of solder bumps 130, or larger than that of solder bumps 130.

Generally, it will be understood that descriptions of various embodiments herein may be made with reference to solder bumps, however in one or more embodiments the solder bumps may be replaced by a pad or redistribution layer some other type of conductive element that is appropriate to couple two elements of a semiconductor package such as a processing unit or a memory to an interposer. For example, the pad may include copper, gold, aluminum, or some other conductive material. In embodiments, the portions of the semiconductor packages depicted as including solder bumps may include both solder bumps and pads and redistribution layers. However, the pads may not be specifically depicted herein for the sake of clarity of the illustration and lack of clutter.

The interposer 120 may be a semiconductor substrate. Specifically, the interposer 120 may include multi-layered dielectric material such as silicon dioxide, polyimide, epoxy & silicon dioxide composite build-up film, mold, or some other dielectric material. The interposer 120 may include a plurality of conductive elements such as traces or vias. The traces or vias may be formed of one or more conductive materials such as copper, aluminum, gold, or some other conductive material. The conductive elements may form a variety of conductive pathways such as conductive pathways 103/107/111/109/113/117 within the interposer 120. Specifically, the conductive pathways 103/107/111/109/113/117 may include one or more traces or vias. As used herein, a trace may refer to an element that is generally parallel to the face of the interposer 120 to which the memory 115 is coupled, and a “via” may refer to an element that is generally perpendicular to a trace, and which may provide a communicative path from one layer of the interposer 120 to another layer of the interposer.

In some embodiments, the interposer 120 may include memory control logic 150. The memory control logic 150 may be implemented as circuitry, some other type of hardware, firmware, software to be run on a processor of the interposer 120, some other type of logic, or some combination thereof. The memory control logic 150 may be communicatively coupled with both a processing unit 105 and a memory 115, as shown in FIG. 1. Specifically, in some embodiments a conductive pathway such as conductive pathway 107 may communicatively couple a processing unit 105 with a memory 115. A conductive pathway such as conductive pathway 109 may couple a memory 115 to memory controller logic 150. A conductive pathway such as conductive pathway 117 may couple a processing unit 105 with the memory controller logic 150. A conductive pathway such as conductive pathway 103 may couple processing unit 105 the substrate 135. A conductive pathway such as conductive pathway 113 may couple the memory controller logic 150 with the substrate 135. A conductive pathway 111 may couple a memory 115 with the substrate 135. More specifically, the various conductive pathways 103/107/111/109/113/117 may couple with solder bumps 125 or 130, or pads of the interposer 120 (not shown, as discussed above) and allow communication, by the solder bumps 125/130, between the various elements of the semiconductor package 100 and the substrate 135.

The memory control logic 150 may be configured to generate a memory access request based on a signal from the processing unit 105. Specifically, the memory access request may be received by the memory controller logic 150 from processing unit 105 along conductive pathway 117. The memory access request may be, for example, a read or write request that is to either alter data within the memory 115, or interpret data from the memory 115 or additional element 110. As part of the generation of the memory access request, the memory control logic 150 may be able to identify a memory location within the memory 115 to which the read or write command should go. The memory control logic 150 may transmit the memory access request along conductive pathway 109. If the memory access request is a read command, the read data may then be transmitted back along the appropriate conductive pathways 109/117 to memory control logic 150.

In other embodiments, the interposer 120 may be passive as described above. That is, the interposer 120 may not have on-board processing or logic such as memory control logic 150. In these embodiments the memory control logic 150 may be an element of the processing unit 105 or memory 115 as described above. More specifically, in some embodiments the memory control logic 150 may be an element of the processing unit 105 and implemented as hardware, firmware, software, or some combination thereof. In other embodiments, the memory control logic 150 may be separate from but physically and communicatively coupled with the processing unit 105.

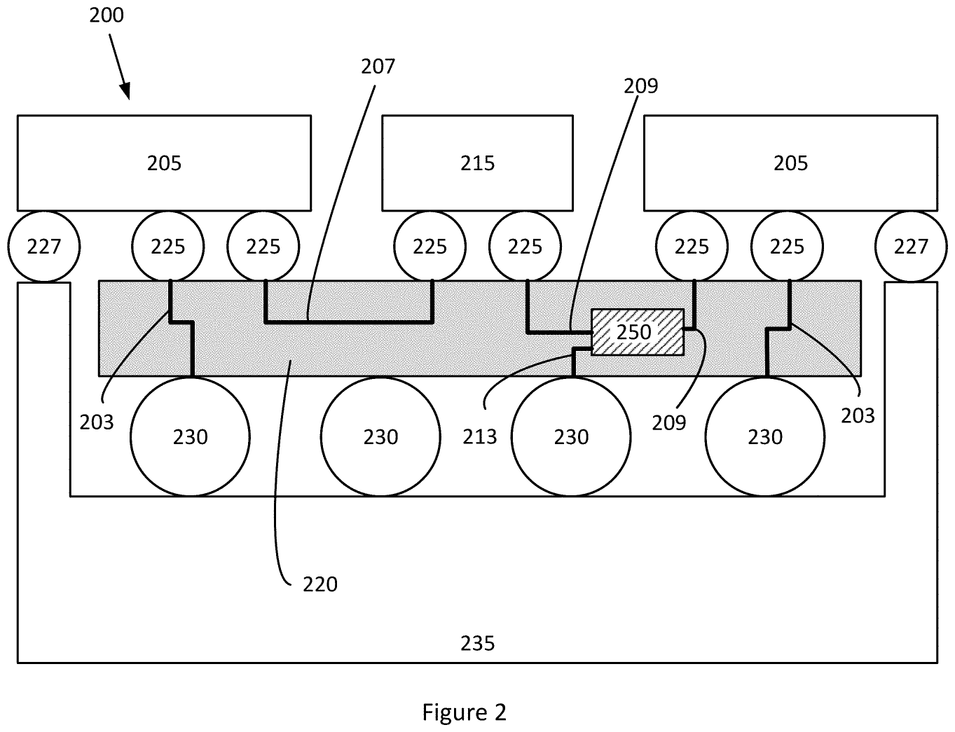

FIG. 2 depicts an alternative semiconductor package with a dual-sided interposer, in accordance with various embodiments. Specifically, FIG. 2 depicts a semiconductor package 200, which may include one or more processing units 205 and the memory 215, which may be respectively similar to processing units 105 and memory 115. The processing unit(s) 205 and the memory 215 may be coupled to an interposer 220 (which may be similar to interposer 120) by solder bumps 225, which may be similar to solder bumps 125. The interposer 220 may be coupled with the substrate 235 (which may be similar to substrate 135) by solder bumps 230, which may be similar to solder bumps 130. The interposer 220 may include a memory control logic 250, which may be similar to memory control logic 150. The interposer 220 may also have one or more conductive pathways such as conductive pathways 203, 207, 209, 213, and 217, which may be respectively similar to conductive pathways 103, 107, 109, 113, and 117.

As shown in FIG. 2, in embodiments the substrate 235 may have a cavity 290, and the semiconductor package 200 may be positioned within the cavity 290. In these embodiments, one or more elements of the semiconductor package 200, for example processing unit(s) 205, may be coupled directly with the substrate 235. Specifically, the processing units 205 may be coupled with the substrate 235 by solder bumps 227, which may be similar to solder bumps 225. Similarly, the interposer 220 may be directly embedded within substrate 235 such that dielectric and conductive pathways surround interposer 220 and the solder bumps 230 may be replaced by directly plated conductive pathways such as copper, aluminum, etc.

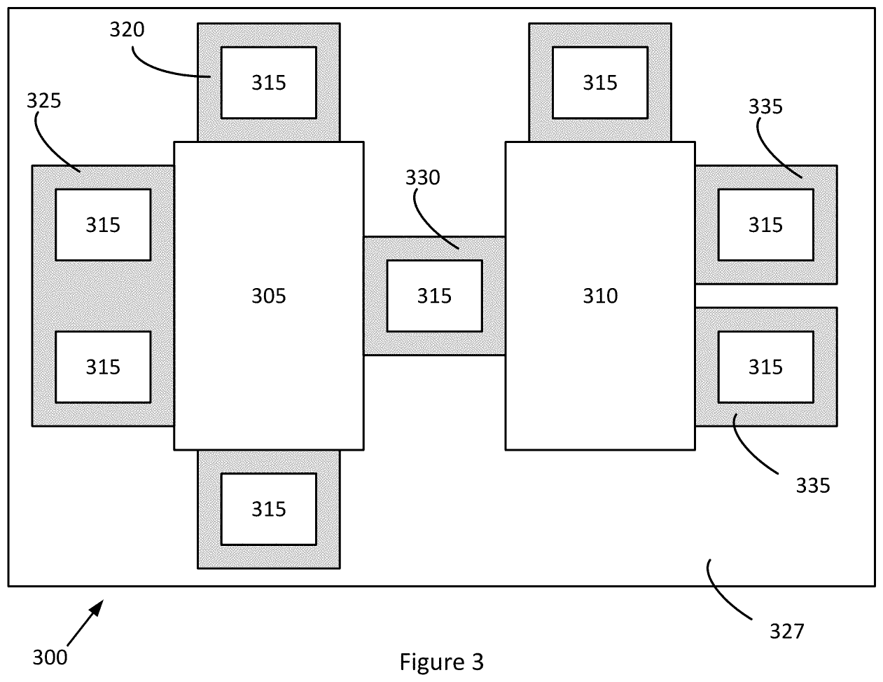

The use of an interposer such as interposers 120 or 220 may allow different possible arrangements for semiconductor packages such as semiconductor package 300, as shown in FIG. 3. Specifically, FIG. 3 depicts a semiconductor package that includes an interposer, and the interposer may be used as a dual-sided bridge between various elements of the package. Specifically, the semiconductor package 300 may include a plurality of processing units 305 and 310, which may be similar to processing units 105 or 205. The semiconductor package 300 may also include a plurality of interposers such as interposers 320/325/330/335, which may be similar to interposers 120 or 220. The semiconductor package 300 may also include a plurality of memories 315, which may be similar to memories 115 or 215. The semiconductor package 300 may also include a substrate 327, which may be similar to substrates 135 or 235. In embodiments, the memories 315 may be positioned on a side of the interposers 320/325/330/335 that is opposite the side of the interposers to which the processing units 305/310 are coupled. In other embodiments, one or more of the memories 315 may be on the same side of the interposers 320/325/330/335 as the side to which the processing units 305/310 are coupled.

As can be seen, one of the interposers such as interposer 330 may be communicatively and physically coupled with both processing units 305 and 310. This coupling with two processing units may be referred to as “stitching” the processing units together. Some processing units, e.g., processing unit 305, may have interposers on each side of the processing unit. More specifically, the interposers 320/325/335 may extend from the processing units 305/310 in a cantilevered fashion. Other processing units, e.g., processing unit 310, may not have an interposer coupled with one or more sides of the processing units. In some embodiments, a processing unit such as processing unit 310 may have two interposers 335 coupled with a single side of the processing unit, and each of the interposers 335 may have a single memory 315 attached thereto. By contrast, a processing unit such as processing unit 305 may be coupled with an interposer such as interposer 325 that has two memories 315 attached thereto.

Semiconductor package 300 may enable a direct bus to the memories 315 from the processing units 305/310, and may be configurable to accommodate various memory heights that range from a single piece of memory to a memory stack.

It will be understood that the example semiconductor package 300 is intended as an example of configuration options, and other embodiments may be arranged differently. For example, in some embodiments a semiconductor package or semiconductor package structure may include more or fewer processing units. In some embodiments one or more of the processing units may have additional or fewer interposers coupled thereto. The various interposers may have more or fewer memories coupled thereto. Although elements such as additional elements 110/210 are not depicted in FIG. 3, in some embodiments the semiconductor packages or semiconductor package structures may still include those additional elements.

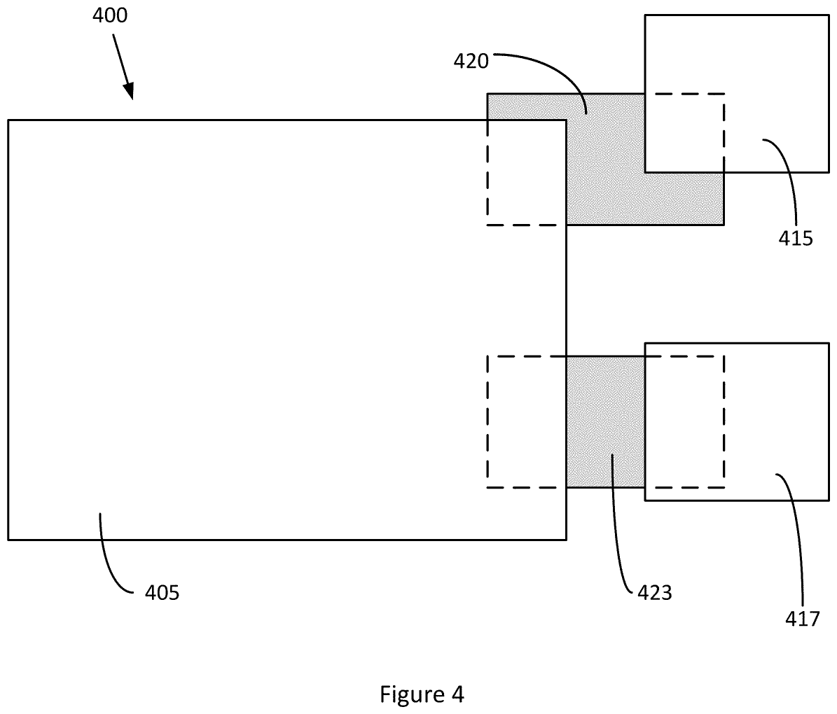

The overlap between an interposer, a processing unit, and a memory may be of a variety of shapes. FIG. 4 depicts a simplified top-down diagram of a semiconductor package structure 400 that may include a processing unit 405. The semiconductor package structure 400 may further include memories 415 and 417, which may each be similar to memory 115. The semiconductor package structure 400 may further include interposers 420 and 423, which may be similar to interposer 120.

As can be seen in FIG. 4, in some embodiments the processing unit 405, the interposer 423, and the memory 417 may be arranged in a relatively linear pattern. Other elements of the semiconductor package structure 400 may be arranged such that they overlap at a corner rather than a side. An example of this arrangement may be as shown with respect to processing unit 405, interposer 420, and memory 415. It will be understood, however, that this arrangement is intended to give an example of different options, and other embodiments may include different arrangements of the various elements. Additionally, other embodiments may include additional or alternative numbers of elements such as the processing unit(s), interposer(s), or memory(s). In some embodiments one of the elements may be arranged relatively linearly (e.g., the processing unit and the interposer) while another of the elements may be non-linear (e.g., the interposer and the memory). Furthermore, in some embodiments the interposers 423 and 420 may be embedded within a package via fan-out or traditional die embedding techniques and then communicatively coupled to the processing unit 405, memory 415, and memory 417, and a printed circuit board below the package.

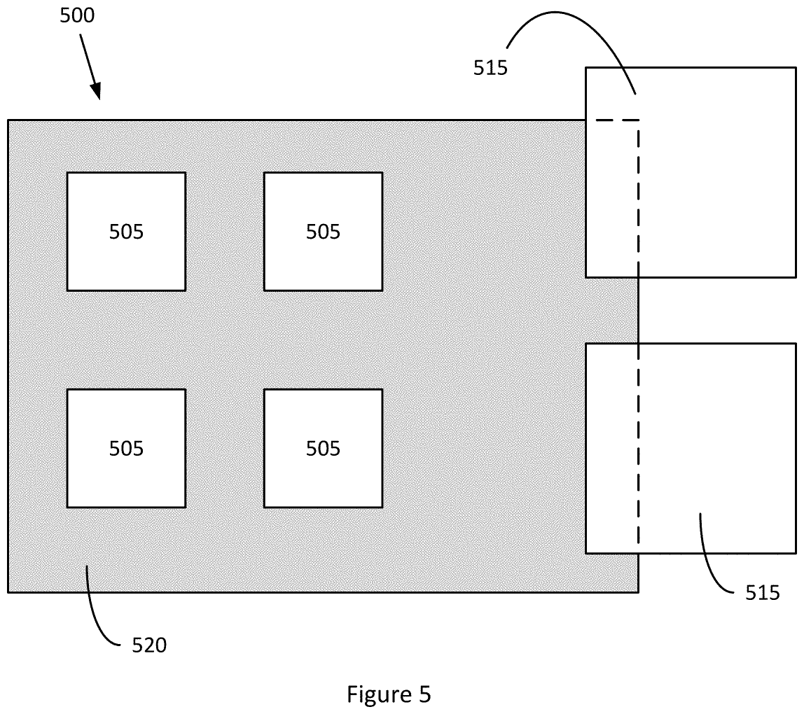

In some embodiments, the proportions of various elements of the semiconductor package structure 400 may be different than as shown in FIG. 4. For example, as shown in FIG. 5, a semiconductor package structure 500 may include an interposer 520, which may be similar to interposer 120. The semiconductor package structure 500 may further include a plurality of processing units 505, which may be similar to processing unit 105. In some embodiments, the processing units 505 may be cores of a multi-core processor, or some other type of processing unit sub-array which, when in combination with interposer 520, form a function similar to a monolithic example of processing unit 505. The semiconductor package structure 500 may further include a plurality of memories 515, which may be similar to memory 115.

Similarly to semiconductor package structure 400, semiconductor package structure 500 is intended to depict a variety of configurations, and other embodiments may have different numbers of elements, or different arrangements of elements. For example, the semiconductor package structure 500 may include more or fewer processing units, memories, etc. Furthermore, in some embodiments the memory control logic may be included in the memory 515, on the interposer 520, or some combination thereof.

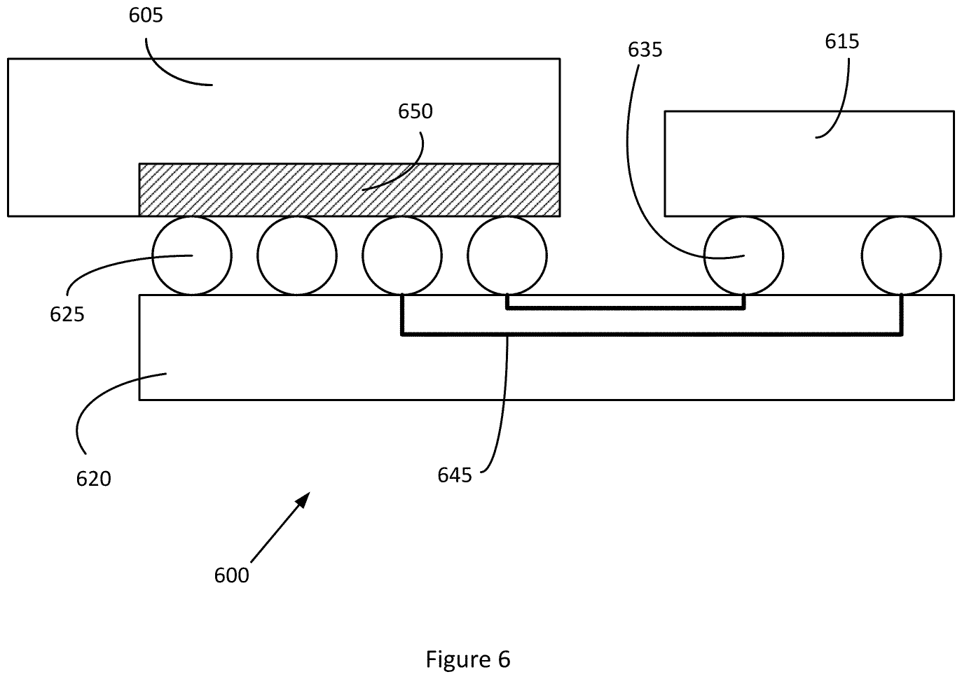

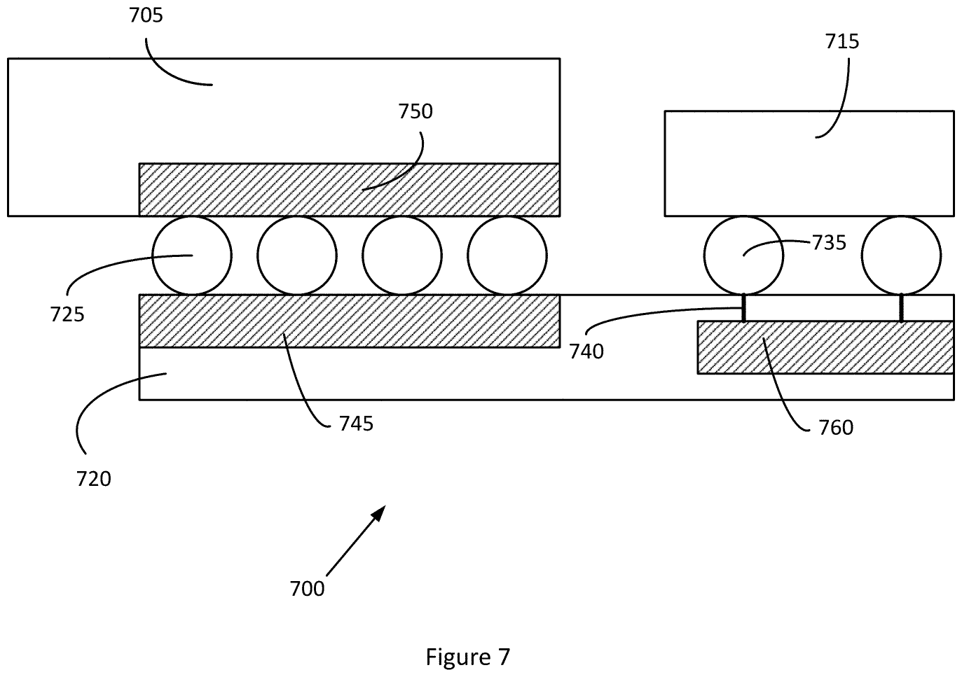

FIGS. 6 and 7 depict example embodiments related to the memory control logic. Specifically, FIG. 6 depicts a semiconductor package structure 600 that may include a processing unit 605, an interposer 620, and a memory 615 which may be respectively similar to processing unit 105, interposer 120, and memory 115. The processing unit 605 may be coupled with the interposer 620 by solder bumps 625, which may be similar to solder bumps 225. Similarly, the memory 615 may be coupled with the interposer 620 by solder bumps 635, which may be similar to solder bumps 225. The interposer 620 may include conductive pathways 645, which may be similar to conductive pathway 207 or some other conductive pathway discussed herein such as conductive pathways 103, 111, 107, etc. In embodiments, interposer 620 may be coupled to a substrate (not shown for the sake of elimination of redundancy) such as substrate 135. The substrate may be coupled with the interposer 620 at a side of the interposer 620 opposite the side to which solder bumps 625 are coupled. The interposer 620 may be coupled with the substrate by solder bumps such as solder bumps 130, assembled joints, or embedding through fan-out or die embedding approaches.

In this embodiment, the interposer 620 may be a passive interposer that has conductive pathways 645 but may not include logic or processing. In other words, the passive interposer may be configured to pass signals between the processing unit 605 and the memory 615, between the 600 and a substrate to which the 600 is coupled, etc., without altering the signals. In this embodiment, the memory control logic 650, which may be similar to memory control logic 150, may be positioned in the processing unit 605. The memory control logic 650 may be configured to transmit a memory access request such as a read or a write command through solder bumps 625, to conductive pathway(s) 645, to solder bump(s) 635 and to the memory 615. The memory access request may be based, for example, on a direction from the processing unit 605. The memory access request may be, for example, a read command that is to identify a value stored in one or more memory cells of the memory 615. Alternatively, the memory access request may be, for example, a write command that is to alter a value of one or more memory cells of the memory 615. In some embodiments, vertical interconnects coupled with the substrate to which the semiconductor package structure 600 is coupled may enable power to be delivered from the substrate directly to the processing unit 605 or memory 615. Furthermore, in some embodiments, control logic may additionally or alternatively be present in the memory.

As an alternative, in some embodiments the interposer may be an active interposer as described above. The use of the active interposer may provide benefits with respect to signal integrity or performance. More specifically, the interposer may be an active interposer that includes some form of logic or processing in the form of hardware, software, firmware, or some combination thereof. More specifically, FIG. 7 depicts a semiconductor package structure 700 that may include a processing unit 705, an interposer 720, and a memory 715, which may be respectively similar to processing unit 105, interposer 120, and memory 115. The interposer 720 may be coupled with processing unit 705 by solder bumps 725, which may be similar to solder bumps 625. The interposer 720 may be coupled with the memory 715 by solder bumps 735, which may be similar to solder bumps 635.

The interposer 720 may include processing logic such as memory control logic 745 and 760. In some embodiments, memory control logic such as memory control logic 760 may be coupled with an element such as memory 715 by a conductive element such as conductive elements 740, which may be, e.g., vias. Alternatively, memory control logic such as memory control logic 745 may be coupled with an element such as processing unit 705. In some embodiments, processing unit 705 or memory 715 may additionally include some portion of memory control logic 750. In embodiments, memory control logics 750, 745, and 760 may each be similar to memory control logic 150, while in other embodiments the memory control logics 745/750/760 may be disaggregated elements of a single memory control logic.

It will be understood that the elements of FIGS. 6 and 7 are intended as examples, and other embodiments may include alternative arrangements. For example, in some embodiments the interposer 720 may only include one of memory control logic 745 and 760, or memory control logic 745 and 760 may be combined into a single memory control logic. In some embodiments, memory control logic 745 may be coupled with the processing unit 705 by conductive elements 740, or memory control logic 760 may be included in the memory 715. In some embodiments, the conductive elements 740 may include traces in addition to, or in place of, the depicted vias. In some embodiments, memory control logics 745 and 760 may be coupled with one another by conductive elements (not shown).

In greater specificity, in legacy semiconductor packages or semiconductor package structures where the memory may be a memory stack that includes two or more slices, the memory may include a memory control logic that is positioned in the center of the memory stack. The memory control logic may include a physical layer (PHY) logic that is at the edge of the memory control logic.

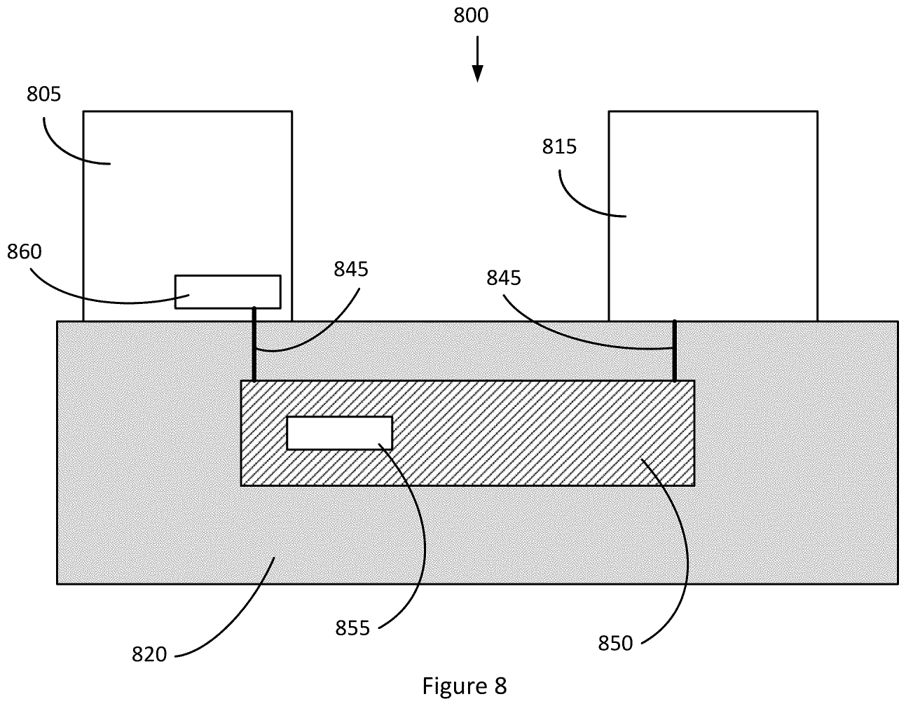

However, if the memory control logic is added to the interposer or some other portion of the semiconductor package or semiconductor package structure, then the semiconductor package or semiconductor package structure may be configured to allow direct access to the memory stacks. FIG. 8 depicts a simplified example semiconductor package structure 800 that may allow for direct memory access. More generally, FIG. 8 depicts an example semiconductor package structure where certain structural elements such as solder bumps, redistribution layers, package or printed circuit board or some other elements may not be depicted. Specifically, the semiconductor package structure 800 may include a processing unit 805, an interposer 820, and a memory 815 which may be respectively similar to processing unit 105, interposer 120, and memory 115. The interposer 820 may include memory control logic 850, which may be similar to memory control logic 150.

The memory control logic 850 may be communicatively coupled with the processing unit 805 and memory 815 by conductive elements 845. Generally, as shown in FIG. 8, conductive elements 845 may be similar to conductive elements 740. More specifically, the conductive elements 845 may be as shown in FIG. 8, however in other embodiments conductive elements 845 may additionally or alternatively include traces, redistribution layers, solder bumps such as solder bumps 125, or some other type of conductive elements.

In some embodiments, the memory control logic 850 may include physical layer (PHY) layer logic 855. Similarly, the processing unit 805 may include PHY layer logic 860 that is communicatively coupled with the PHY layer logic 855 of memory control logic 850 by conductive elements 845. Generally, the memory control logic 850, and more particularly the PHY layer logic 855 may be configured to send a memory access request such as a read or write request to the memory 815 using conductive element 845. The memory access request may be based on a signal received from PHY layer logic 860 of the processing unit 805.

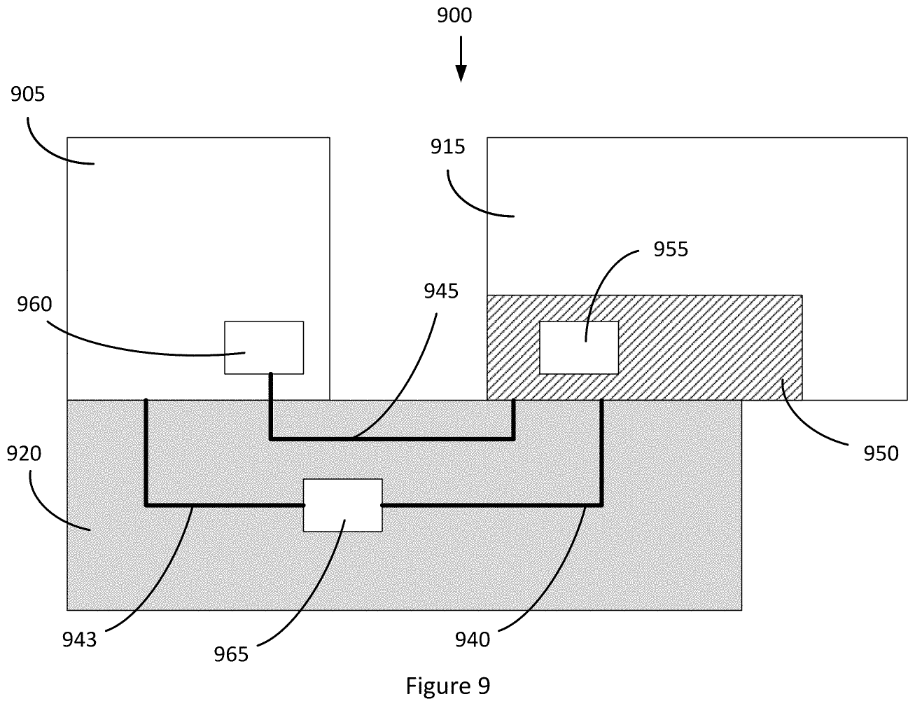

FIG. 9 depicts an alternative simplified example semiconductor package structure 900 that may allow for direct memory access. Specifically, the semiconductor package structure 900 may include a processing unit 905, and interposer 920, and a memory 915, which may be respectively similar to processing unit 105, interposer 120, and memory 115. The processing unit 905 may include a PHY layer logic 960, which may be similar to PHY layer logic 860. Similarly, the interposer 920 may include the PHY layer logic 965, which may be similar to PHY layer logic 860. The memory 915 may include a memory control logic 950 with a PHY layer logic 955, which may be respectively similar to memory control logic 850 and PHY layer logic 855.

In embodiments the PHY layer logic 960 of processing unit 905 may be communicatively coupled to the memory control logic 950 by way of conductive pathways 945, which may generally be similar to conductive pathways 103/107/111/109/113/117/etc., and which may include one or more vias, traces, or solder bumps. Similarly, the processing unit 905 and the memory control logic 950 may be communicatively coupled with PHY layer logic 965 by way of conductive pathways 943 and 940, which may likewise be similar to conductive pathways 103/107/111/109/113/117/etc., and which may include one or more vias, traces, or solder bumps.

Similarly to PHY layer logic 855, memory control logic 950, and more particularly PHY layer logic 955, may be configured to send a memory access request to memory 915. The memory access request may be based on, for example, a signal received from PHY layer logic 960 by way of conductive pathways 945. Additionally or alternatively, the memory access request may be based on a signal received from PHY layer logic 965 by way of conductive pathway 940. In this embodiment, the signal may be based on a request received from processing unit 905 by way of conductive pathway 943.

It will be understood the FIG. 9 is intended to show examples that may be used in various embodiments. In some embodiments, the semiconductor package structure 900 may include both PHY layer logics 960 and 965, while in other embodiments the semiconductor package structure 900 may include only one of PHY layer logic 960 or PHY layer logic 965. Semiconductor package structure 900 may provide the benefit that if PHY layer logic 955 is located in a portion of memory control logic 950 closer to the processing unit 905, then interposer 920 may be allowed to have a relatively shorter lateral length or width.

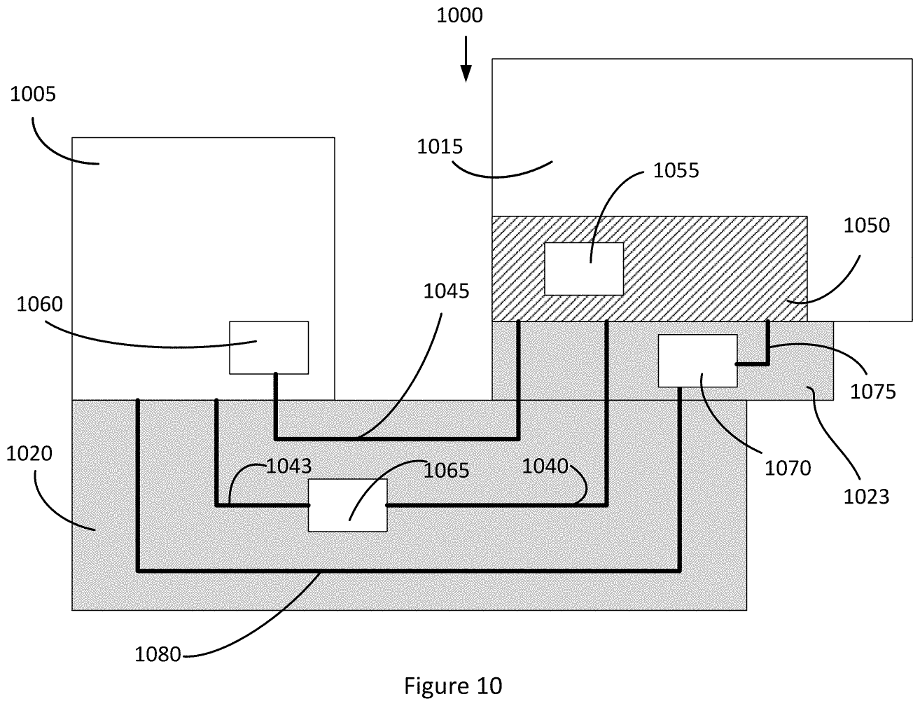

In some embodiments, it may be desirable to introduce an additional interposer between the memory and the interposer that is coupled with the processing unit. FIG. 10 provides an example semiconductor package structure 1000 that may include this additional interposer, while still allowing for direct memory access and other benefits of the semiconductor package structures 800 and 900.

Specifically, semiconductor package structure 1000 may include a processing unit 1005, and interposer 1020, and a memory 1015, which may be respectively similar to processing unit 105, interposer 120, and memory 115. The memory 1015 may include a memory control logic 1050 with a PHY layer logic 1055, which may be respectively similar to memory control logic 850 and PHY layer logic 855.

Semiconductor package structure 1000 may additionally include interposer 1023. Interposer 1023 may be similar to interposer 1020. Specifically, in embodiments interposer 1023 may be an active or passive interposer, as discussed above. Interposer 1023 may include one or more conductive elements such as vias or traces, and in some embodiments interposer 1023 may be semiconductor substrate, as described above.

In some embodiments, processing unit 1005 may include a PHY layer logic 1060, which may be similar to PHY layer logic 960. The PHY layer logic 1060 may be communicatively coupled with the memory control logic 1050 by way of conductive pathway 1045, which may be similar to conductive pathway 945 and which may include one or more traces, vias, solder balls, redistribution layers, or some other conductive element.

Additionally or alternatively, interposer 1020 may include PHY layer logic 1065, which may be similar to PHY layer logic 965. PHY layer logic 1065 may be communicatively coupled with the memory control logic 1050 by way of conductive pathway 1040, and further communicatively coupled with processing unit 1005 by way of conductive pathway 1043. Conductive pathways 1040 and 1043 may be respectively similar to conductive pathways 943 and 940.

Additionally or alternatively, interposer 1023 may include a PHY layer logic 1070, which may be generally similar to PHY layer logic 965. PHY layer logic 1070 may be communicatively coupled with memory control logic 1050 by way of conductive pathway 1075. Similarly, PHY layer logic 1070 may be communicatively coupled with processing unit 1005 by conductive pathway 1080. Generally, conductive pathways 1075 and 1080 may be similar to conductive pathways 1045, 1043, or 1040, and include one or more vias, solder bumps, redistribution layers, traces, or some other conductive element.

Similarly to semiconductor package structure 900, in embodiments the memory control logic 1050, and particularly PHY layer logic 1055, may be configured to perform one or more memory access requests based on a signal received from PHY layer logic 1070, PHY layer logic 1065, or PHY layer logic 1060. Additionally, similarly to semiconductor package structure 900, it will be understood that the simplified example of FIG. 10 is intended to provide examples of various alternative configurations that may be used in various embodiments. In some embodiments, all three of PHY layer logic 1070, 1065, or 1060 may be present, while in other embodiments one or two of the PHY layer logics 1060/1065/1070 may not be present in a semiconductor package or semiconductor package structure. In some embodiments, memory control logic 1050, and particularly PHY layer logic 1055, may not be present in the memory 1015, but instead may be positioned in the interposer 1023 and coupled with the memory 1015 by conductive pathway 1075.

Semiconductor package structure 1000 may provide various benefits. For example, in some embodiments the interposer 1023 may be configured to help spread heat generated from memory control logic 1050 downward into a substrate (if semiconductor package structure 1000 is coupled with a substrate such as substrates 135 or 235). In some embodiments, the interposer 1023 may include further elements (not shown) to dissipate heat generated by the memory 1015, thereby allowing higher operating bandwidths without exceeding temperature considerations.

Generally, as previously noted, it will be understood that the various semiconductor packages, semiconductor package structures, or systems depicted in FIGS. 1-10 are intended as examples. Unless otherwise stated, embodiments may have more or fewer elements than depicted in the various Figures, or the elements may be arranged in a different manner. For example, various embodiments may have more or fewer processing units, memories, conductive pathways, etc. than are shown in certain of the Figures, or the existing elements may be placed in a different location than shown in the Figures. Additionally, it will be understood that although the terms “semiconductor package” or “semiconductor package structure” may be used with respect to various ones of FIGS. 1-10, the Figures may either show a semiconductor package, a semiconductor package structure which may be used in a semiconductor package, or some other combination of elements. For example, in some embodiments semiconductor package structures 400, 500, 600, 700, 800, 900, or 1000 may be considered to be sub-structures or sub-packages which may be incorporated into a larger semiconductor package.

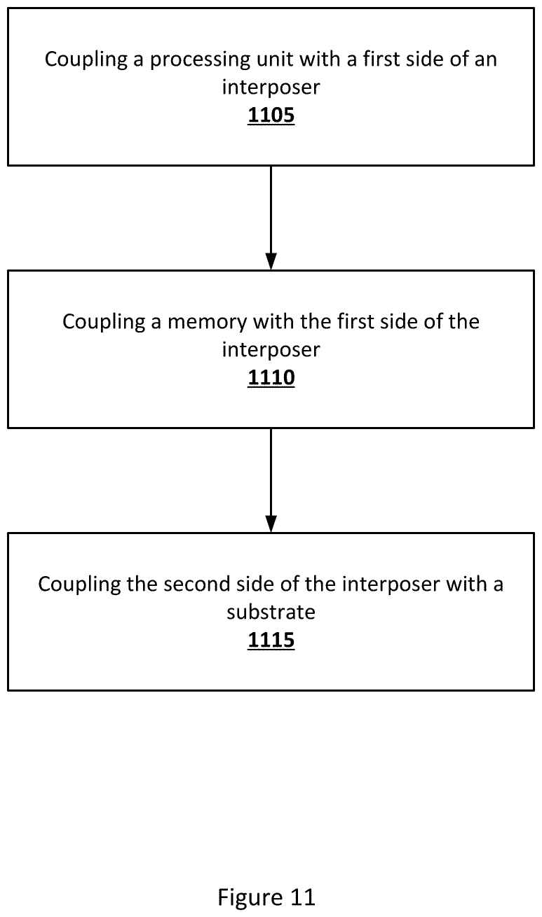

FIG. 11 depicts an example technique that may be used to manufacture one or more of the semiconductor packages or semiconductor package structures depicted herein, in accordance with various embodiments. Specifically, FIG. 11 may be described with respect to FIG. 1, however it will be understood that the technique may likewise apply to the semiconductor packages, semiconductor package structures, or systems depicted in one or more of FIGS. 2-10, with or without adaptation.

The technique may include coupling, at 1105, a processing unit with a first side of an interposer. The processing unit may be, for example, processing unit 105. The interposer may be, for example, interposer 120. The technique may further include coupling, at 1110, a memory with the first side of the interposer. The memory may be, for example, memory 115. The technique may further include coupling, at 1115, the second side of the interposer with a substrate. The substrate may be, for example, substrate 135.

It will be understood that elements of this technique may be performed in a different order than depicted in FIG. 11. For example, in embodiments, element 1115 may be performed prior to one or both of elements 1105 and 1110 for example by embedding interposer 120 in substrate 135 using fan-out or an alternative die embedding techniques. In some embodiments, elements 1105 and 1110 may be performed concurrently. In some embodiments, there may be additional elements to the technique such as further coupling an interposer such as interposer 1023 to the memory or the first interposer. Some embodiments may include forming a cavity within the substrate prior to coupling the interposer to the substrate.

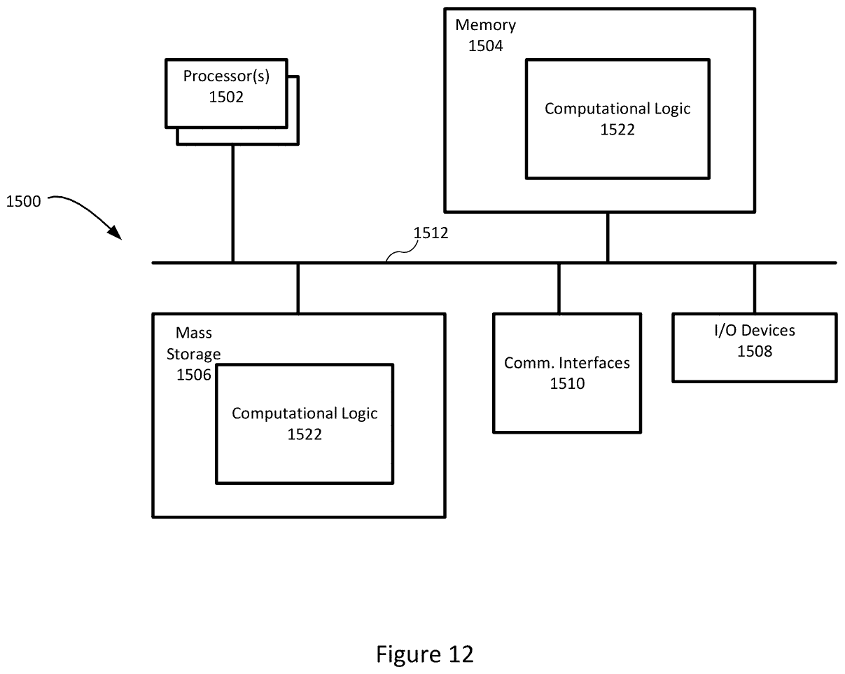

FIG. 12 illustrates an example computing device 1500 suitable for use with semiconductor packages 100, 200, or 300, or semiconductor package structures 400, 500, 600, 700, 800, 900, or 1000 in accordance with various embodiments. Specifically, in some embodiments, the computing device 1500 may include semiconductor packages 100, 200, or 300, or semiconductor package structures 400, 500, 600, 700, 800, 900, or 1000 therein.

As shown, computing device 1500 may include one or more processors or processor cores 1502 and system memory 1504. For the purpose of this application, including the claims, the terms “processor” and “processor cores” may be considered synonymous, unless the context clearly requires otherwise. The processor 1502 may include any type of processors, such as a CPU, a microprocessor, and the like. The processor 1502 may be implemented as an integrated circuit having multi-cores, e.g., a multi-core microprocessor. The computing device 1500 may include mass storage devices 1506 (such as diskette, hard drive, volatile memory (e.g., dynamic random-access memory (DRAM), compact disc read-only memory (CD-ROM), digital versatile disk (DVD), and so forth)). In general, system memory 1504 and/or mass storage devices 1506 may be temporal and/or persistent storage of any type, including, but not limited to, volatile and non-volatile memory, optical, magnetic, and/or solid state mass storage, and so forth. Volatile memory may include, but is not limited to, static and/or dynamic random-access memory. Non-volatile memory may include, but is not limited to, electrically erasable programmable read-only memory, phase change memory, resistive memory, and so forth.

The computing device 1500 may further include input/output (I/O) devices 1508 (such as a display (e.g., a touchscreen display), keyboard, cursor control, remote control, gaming controller, image capture device, and so forth) and communication interfaces 1510 (such as network interface cards, modems, infrared receivers, radio receivers (e.g., Bluetooth), and so forth).

The communication interfaces 1510 may include communication chips (not shown) that may be configured to operate the computing device 1500 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 1510 may operate in accordance with other wireless protocols in other embodiments.

The above-described computing device 1500 elements may be coupled to each other via system bus 1512, which may represent one or more buses. In the case of multiple buses, they may be bridged by one or more bus bridges (not shown). Each of these elements may perform its conventional functions known in the art. The various elements may be implemented by assembler instructions supported by processor(s) 1502 or high-level languages that may be compiled into such instructions.

The permanent copy of the programming instructions may be placed into mass storage devices 1506 in the factory, or in the field, through, for example, a distribution medium (not shown), such as a compact disc (CD), or through communication interface 1510 (from a distribution server (not shown)). That is, one or more distribution media having an implementation of the agent program may be employed to distribute the agent and to program various computing devices.

The number, capability, and/or capacity of the elements 1508, 1510, 1512 may vary, depending on whether computing device 1500 is used as a stationary computing device, such as a set-top box or desktop computer, or a mobile computing device, such as a tablet computing device, laptop computer, game console, or smartphone. Their constitutions are otherwise known, and accordingly will not be further described.

For one embodiment, at least one of processors 1502 may be packaged together with computational logic 1522 configured to practice aspects of optical signal transmission and receipt described herein to form a System in Package (SiP) or a System on Chip (SoC).

In various implementations, the computing device 1500 may comprise one or more components of a data center, a laptop, a netbook, a notebook, an ultrabook, a smartphone, a tablet, a personal digital assistant (PDA), an ultra mobile PC, a mobile phone, or a digital camera. In further implementations, the computing device 1500 may be any other electronic device that processes data.

In embodiments, various of the elements described with respect to computing device 1500 may be a component of one of the semiconductor packages or semiconductor package structures discussed herein. For example, the processor(s) 1502 may be processing unit 105 or a processor of some other semiconductor package or semiconductor package structure herein. Memory 1504 or mass storage device 1506 may be memory 115 or a memory of some other semiconductor package or semiconductor package structure herein.

### EXAMPLES OF VARIOUS EMBODIMENTS

Example 1 includes a semiconductor package structure comprising: an interposer with a first side and a second side opposite the first side, wherein the first side of the interposer is to couple with a substrate with first solder bumps with a first pitch; a memory coupled with the second side of the interposer by solder bumps with a second pitch; and a processing unit coupled with the second side of the interposer by solder bumps with a third pitch; wherein the processing unit and the memory are communicatively coupled with one another by the interposer, and wherein the processing unit and the memory are communicatively coupled with the substrate by the interposer when the interposer is coupled with the substrate.

Example 2 includes the semiconductor package structure of example 1, wherein the first pitch is greater than the second pitch or the third pitch.

Example 3 includes the semiconductor package structure of example 1, wherein the interposer is embedded within the substrate.

Example 4 includes the semiconductor package structure of any of examples 1-3, wherein the memory is a dynamic random-access memory (DRAM), a non-volatile memory (NVM), an embedded DRAM (eDRAM), a static random-access memory (SRAM), a memory stack that includes a first memory slice and a second memory slice, or a high bandwidth memory (HBM) that is to use a bus with a minimum bandwidth of 256 bits per second.

Example 5 includes the semiconductor package structure of any of examples 1-3, wherein the processing unit is a central processing unit (CPU), a general processing unit (GPU), a core of a multi-core processor, or a field programmable gate array (FPGA).

Example 6 includes the semiconductor package structure of any of examples 1-3, wherein the memory is a first memory, and further comprising a second memory coupled with the second side of the interposer.

Example 7 includes the semiconductor package structure of any of examples 1-3, wherein the processing unit is a first processing unit, and further comprising a second processing unit coupled with the second side of the interposer.

Example 8 includes the semiconductor package structure of any of examples 1-3, wherein the processing unit, the interposer, or the memory, include memory control logic that is to perform a memory access command on the memory.

Example 9 includes the semiconductor package structure of example 8, wherein the memory control logic includes a first physical layer (PHY) logic that is communicatively coupled with a second PHY logic.

Example 10 includes a semiconductor package structure comprising: a first interposer with a first side and a second side opposite the first side, wherein the first side of the first interposer is to communicatively and physically couple with a substrate; a processing unit communicatively and physically coupled with the second side of the first interposer; a second interposer with a first side the second side opposite the first side, wherein the first side of the second interposer is communicatively and physically coupled with the second side of the first interposer; and a memory communicatively and physically coupled with the second side of the second interposer.

Example 11 includes the semiconductor package structure of example 10, wherein the memory is a dynamic random-access memory (DRAM), a non-volatile memory (NVM), an embedded DRAM (eDRAM), a static random-access memory (SRAM), a memory stack that includes a first memory slice and a second memory slice, or a high bandwidth memory (HBM) that is to use a bus with a minimum bandwidth of 256 bits per second.

Example 12 includes the semiconductor package structure of example 10, wherein the processing unit is a central processing unit (CPU), a general processing unit (GPU), a core of a multi-core processor, or a field programmable gate array (FPGA).

Example 13 includes the semiconductor package structure of any of examples 10-12, wherein the memory is a first memory, and further comprising a second memory coupled with the second side of the interposer.

Example 14 includes the semiconductor package structure of any of examples 10-12, wherein the processing unit is a first processing unit, and further comprising a second processing unit coupled with the second side of the first interposer.

Example 15 includes the semiconductor package structure of any of examples 10-12, wherein the first interposer includes a memory control logic with a physical layer (PHY) logic, wherein the PHY logic is to identify a memory access command related to the memory, the memory access command received from a PHY logic of the processing unit.

Example 16 includes the semiconductor package structure of any of examples 10-12, wherein the memory includes a memory control logic with a physical layer (PHY) logic, wherein the PHY logic is to identify a memory access command related to the memory, the memory access command received from a PHY logic of the processing unit, a PHY logic of the first interposer, or a PHY logic of the second interposer.

Example 17 includes a semiconductor package comprising: a substrate; an interposer with a first side and a second side opposite the first side, wherein the first side of the interposer is communicatively and physically coupled with the substrate; a processing unit communicatively and physically coupled with the second side of the interposer; and a memory communicatively and physically coupled with the second side of the interposer such that the processing unit and the memory are communicatively coupled with one another by the interposer, and wherein the processing unit and the memory are communicatively coupled with the substrate by the interposer.

Example 18 includes the semiconductor package of example 17, wherein the memory or the processing unit are communicatively coupled with the substrate by the interposer.

Example 19 includes the semiconductor package of example 17, wherein the memory and the processing unit are communicatively coupled with one another by the interposer.

Example 20 includes the semiconductor package of example 17, wherein the interposer is at least partially embedded within the substrate.

Example 21 includes the semiconductor package of any of examples 17-20, wherein the processing unit is a first processing unit, and further comprising a second processing unit coupled with the interposer.

Example 22 includes the semiconductor package of example 21, wherein the interposer is a first interposer and further comprising a second interposer, wherein the second interposer includes a first side coupled with the substrate and a second side opposite the first side, wherein the second side of the second interposer is coupled with the second processing unit.

Example 23 includes the semiconductor package of any of examples 17-20, wherein the memory is a first memory, and further comprising a second memory coupled with the interposer.

Example 24 includes the semiconductor package of any of examples 17-20, wherein the memory is a dynamic random-access memory (DRAM), a non-volatile memory (NVM), an embedded DRAM (eDRAM), a static random-access memory (SRAM), a memory stack that includes a first memory slice and a second memory slice, or a high bandwidth memory (HBM) that is to use a bus with a minimum bandwidth of 256 bits per second.

Example 25 includes the semiconductor package of any of examples 17-20, wherein the processing unit is a central processing unit (CPU), a general processing unit (GPU), a core of a multi-core processor, or a field programmable gate array (FPGA).

Example 26 includes a method of forming a semiconductor package, the method comprising: coupling a processing unit with a first side of an interposer, wherein the interposer has the first side and a second side opposite the first side; coupling a memory with the first side of the interposer; and coupling the second side of the interposer with a substrate; wherein the processing unit and the memory are communicatively coupled with one another by the interposer and, after the interposer is coupled with the substrate, the processing unit and the memory are communicatively coupled with the substrate by the interposer.

Example 27 includes the method of example 26, further comprising at least partially embedding the interposer within the substrate.

Example 28 includes the method of example 26, wherein the processing unit is a first processing unit, and the memory is a first memory, and further comprising coupling a second processing unit or a second memory with the first side of the interposer.

Example 29 includes the method of any of examples 26-28, further comprising: coupling the memory or the processing unit with the first side of the interposer by first solder bumps with a first pitch; and coupling the second side of the interposer with the substrate by a redistribution layer and second solder bumps with a second pitch.

Example 30 includes the method of example 29, wherein the second pitch is greater than the first pitch.

Example 31 includes the method of any of examples 26-28, wherein the memory is a dynamic random-access memory (DRAM), a non-volatile memory (NVM), an embedded DRAM (eDRAM), a static random-access memory (SRAM), a memory stack that includes a first memory slice and a second memory slice, or a high bandwidth memory (HBM) that is to use a bus with a minimum bandwidth of 256 bits per second.

Example 32 includes the method of any of examples 26-28, wherein the processing unit is a central processing unit (CPU), a general processing unit (GPU), a core of a multi-core processor, or a field programmable gate array (FPGA).

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations of the various embodiments, including what is described in the Abstract, is not intended to be exhaustive or to limit embodiments to the precise forms disclosed. While specific implementations of, and examples for, various embodiments are described herein for illustrative purposes, various equivalent modifications are possible, as those skilled in the relevant art will recognize. These modifications may be made in light of the above detailed description. The terms used in the following claims should not be construed to limit this disclosure to the specific embodiments disclosed in the specification and the claims.

1. A semiconductor package structure comprising:
an interposer with a first side and a second side opposite the first side, wherein the first side of the interposer is to couple with a substrate with first solder bumps with a first pitch;
a memory coupled with the second side of the interposer by solder bumps with a second pitch; and
a processing unit coupled with the second side of the interposer by solder bumps with a third pitch;
wherein the processing unit and the memory are communicatively coupled with one another by the interposer, and wherein the processing unit and the memory are communicatively coupled with the substrate by the interposer when the interposer is coupled with the substrate.

2. The semiconductor package structure of claim 1, wherein the first pitch is greater than the second pitch or the third pitch.

3. The semiconductor package structure of claim 1, wherein the interposer is embedded within the substrate.

4. The semiconductor package structure of claim 1, wherein the memory is a first memory, and the semiconductor package structure further includes a second memory coupled with the second side of the interposer.

5. The semiconductor package structure of claim 1, wherein the processing unit is a first processing unit, and the semiconductor package structure further includes a second processing unit coupled with the second side of the interposer.

6. The semiconductor package structure of claim 1, wherein the processing unit, the interposer, or the memory include memory control logic that is to perform a memory access command on the memory.

7. A semiconductor package structure comprising:
a first interposer with a first side and a second side opposite the first side, wherein the first side of the first interposer is to communicatively and physically couple with a substrate;
a processing unit communicatively and physically coupled with the second side of the first interposer;
a second interposer with a first side and a second side opposite the first side, wherein the first side of the second interposer is communicatively and physically coupled with the second side of the first interposer; and
a memory communicatively and physically coupled with the second side of the second interposer.

8. The semiconductor package structure of claim 7, wherein the memory is a dynamic random-access memory (DRAM), a non-volatile memory (NVM), an embedded DRAM (eDRAM), a static random-access memory (SRAM), a memory stack that includes a first memory slice and a second memory slice, or a high bandwidth memory (HBM) that is to use a bus with a minimum bandwidth of 256 bits per second.

9. The semiconductor package structure of claim 7, wherein the processing unit is a central processing unit (CPU), a general processing unit (GPU), a core of a multi-core processor, or a field programmable gate array (FPGA).

10. The semiconductor package structure of claim 7, wherein the first interposer includes a memory control logic with a physical layer (PHY) logic, wherein the PHY logic is to identify a memory access command related to the memory, the memory access command received from a PHY logic of the processing unit.

11. The semiconductor package structure of claim 7, wherein the memory includes a memory control logic with a physical layer (PHY) logic, wherein the PHY logic is to identify a memory access command related to the memory, the memory access command received from a PHY logic of the processing unit, a PHY logic of the first interposer, or a PHY logic of the second interposer.

12. A semiconductor package comprising:
a substrate;
an interposer with a first side and a second side opposite the first side, wherein the first side of the interposer is communicatively and physically coupled with the substrate;
a processing unit communicatively and physically coupled with the second side of the interposer; and
a memory communicatively and physically coupled with the second side of the interposer such that the processing unit and the memory are communicatively coupled with one another by the interposer, and wherein the processing unit and the memory are communicatively coupled with the substrate by the interposer.

13. The semiconductor package of claim 12, wherein the memory or the processing unit are communicatively coupled with the substrate by the interposer.

14. The semiconductor package of claim 12, wherein the memory and the processing unit are communicatively coupled with one another by the interposer.

15. The semiconductor package of claim 12, wherein the interposer is at least partially embedded within the substrate.

16. The semiconductor package of claim 12, wherein the processing unit is a first processing unit, and further comprising a second processing unit coupled with the interposer.

17. The semiconductor package of claim 12, wherein the memory is a first memory, and further comprising a second memory coupled with the interposer.

18. The semiconductor package of claim 12, wherein the memory is a dynamic random-access memory (DRAM), a non-volatile memory (NVM), an embedded DRAM (eDRAM), a static random-access memory (SRAM), a memory stack that includes a first memory slice and a second memory slice, or a high bandwidth memory (HBM) that is to use a bus with a minimum bandwidth of 256 bits per second.

19. The semiconductor package of claim 12, wherein the processing unit is a central processing unit (CPU), a general processing unit (GPU), a core of a multi-core processor, or a field programmable gate array (FPGA).

20. A method of forming a semiconductor package, the method comprising:
coupling a processing unit with a first side of an interposer, wherein the interposer has the first side and a second side opposite the first side;
coupling a memory with the first side of the interposer; and
coupling the second side of the interposer with a substrate;
wherein the processing unit and the memory are communicatively coupled with one another by the interposer and, after the interposer is coupled with the substrate, the processing unit and the memory are communicatively coupled with the substrate by the interposer.

21. The method of claim 20, further comprising at least partially embedding the interposer within the substrate.

22. The method of claim 20, wherein the processing unit is a first processing unit, and the memory is a first memory, and further comprising coupling a second processing unit or a second memory with the first side of the interposer.

23. The method of claim 20, further comprising:
coupling the memory or the processing unit with the first side of the interposer by first solder bumps with a first pitch; and
coupling the second side of the interposer with the substrate by a redistribution layer and second solder bumps with a second pitch.

24. The method of claim 20, wherein the memory is a dynamic random-access memory (DRAM), a non-volatile memory (NVM), an embedded DRAM (eDRAM), a static random-access memory (SRAM), a memory stack that includes a first memory slice and a second memory slice, or a high bandwidth memory (HBM) that is to use a bus with a minimum bandwidth of 256 bits per second.

25. The method of claim 20, wherein the processing unit is a central processing unit (CPU), a general processing unit (GPU), a core of a multi-core processor, or a field programmable gate array (FPGA).
